(19) United States
(12) Patent Application Publication
(10) Pub. No.: US 2026/0101738 A1
(43) Pub. Date: Apr. 9, 2026

(54) SEMICONDUCTOR PACKAGE AND METHOD OF MANUFACTURING THE SAME

(71) Applicant: Samsung Electronics Co., Ltd., Suwon-si (KR)

(72) Inventors: Jooyoung CHOI, Suwon-si (KR); Jaeseong Kim, Suwon-si (KR); Jeongseok Kim, Suwon-si (KR); Taewook Kim, Suwon-si (KR); Yejin Lee, Suwon-si (KR); Sangseok Hong, Suwon-si (KR)

(73) Assignee: Samsung Electronics Co., Ltd., Suwon-si (KR)

(21) Appl. No.: 19/219,395

(22) Filed: May 27, 2025

(30) Foreign Application Priority Data
Sep. 24, 2024 (KR) 10-2024-0129434

(51) Int. Cl. H01L 23/00; H01L 23/31; H01L 23/48; H01L 25/065

(52) U.S. Cl. CPC H10W 20/20; H10W 74/114; H10W 90/00; H10W 74/15; H10W 90/722; H10W 90/732

(57) ABSTRACT

A semiconductor package includes a plurality of semiconductor chips staked in a vertical direction, a plurality of bonding structures coupling two adjacent semiconductor chips from among the plurality of semiconductor chips, and an insulating structure at least partially surrounding the plurality of semiconductor chips and the plurality of bonding structures. The plurality of semiconductor chips include a first semiconductor to an n^{th} semiconductor chip. n is a positive integer greater than one (1). The two adjacent semiconductor chips include a lower-layer semiconductor chip and an upper-layer semiconductor chip. Each bonding structure of the plurality of bonding structures includes a connection via and a solder material layer. The connection via extends vertically from an upper pad of the lower-layer semiconductor chip to a lower pad of the upper-layer semiconductor chip. The solder material layer is inside the connection via.

### CROSS-REFERENCE TO RELATED APPLICATIONS

This application claims benefit of priority under 35 U.S.C. § 119 to Korean Patent Application No. 10-2024-0129434, filed on Sep. 24, 2024, in the Korean Intellectual Property Office, the disclosure of which is incorporated by reference herein in its entirety.

### BACKGROUND

### 1. Field

The present disclosure relates generally to semiconductor packages, and more particularly, to a semiconductor package including a plurality of semiconductor chips.

### 2. Description of Related Art

A semiconductor package may refer to a plurality of integrated circuit chips and/or semiconductor chips that may be implemented in a form that may be suitable for use in electronic devices and/or products. In general, in a semiconductor package, a semiconductor chip may be mounted on a printed circuit board, and/or the semiconductor chip and the printed circuit board may be electrically connected to each other using, for example, bonding wires and/or bumps. Recent developments in an electronics industry may be directed towards research to potentially reduce thicknesses of semiconductor packages while maintaining or increasing a reliability of the semiconductor packages. Typically, micro bumps and/or non-conductive films (NCFs) may be used to implement connections between a plurality of semiconductor chips and/or connections between semiconductor chips and substrates. However, when micro bumps and non-conductive films are used to implement connections in a semiconductor package, voids may form between the micro bumps and the non-conductive films, which may negatively impact the reliability of the semiconductor package.

Thus, there exists a need for further improvements in semiconductor package technology, as the need for reduced thicknesses of semiconductor packages may be constrained by a reduced reliability of the semiconductor packages. Improvements are presented herein. These improvements may also be applicable to other semiconductor technologies.

### SUMMARY

One or more example embodiments of the present disclosure provide a semiconductor package having a reduced vertical thickness, when compared to related semiconductor packages.

However, objects to be achieved by the present disclosure may not limited to the objects described above, and other objects may be clearly understood by those skilled in the art from the following descriptions.

According to an aspect of the present disclosure, a semiconductor package includes a plurality of semiconductor chips staked in a vertical direction, a plurality of bonding structures coupling two adjacent semiconductor chips from among the plurality of semiconductor chips, and an insulating structure at least partially surrounding the plurality of semiconductor chips and the plurality of bonding structures. The plurality of semiconductor chips include a first semiconductor to an n^{th} semiconductor chip. n is a positive integer greater than one (1). The two adjacent semiconductor chips include a lower-layer semiconductor chip and an upper-layer semiconductor chip. Each bonding structure of the plurality of bonding structures includes a connection via and a solder material layer. The connection via extends vertically from an upper pad of the lower-layer semiconductor chip to a lower pad of the upper-layer semiconductor chip. The solder material layer is inside the connection via.

According to an aspect of the present disclosure, a semiconductor package includes a substrate, a semiconductor device on an upper portion of the substrate and including at least one semiconductor chip, a plurality of bonding structures coupling the substrate with the semiconductor device, and an insulating structure on an upper surface of the substrate and at least partially surrounding the plurality of bonding structures. Each of the plurality of bonding structures includes a connection via and a solder material layer. The connection via extends vertically from a lower pad of the semiconductor device to an upper pad of the substrate. An upper surface of the solder material layer is in contact with a lower surface of the lower pad of the semiconductor device. A lower surface of the solder material layer is in contact with an upper surface of an upper pad of the substrate. An outer surface of the solder material layer is in contact with an inner surface of the connection via.

According to an aspect of the present disclosure, a method of manufacturing a semiconductor package includes preparing a plurality of semiconductor chips including a first semiconductor chip to an nth semiconductor chip, sequentially performing a chip connection process of coupling the first semiconductor chip with the (n−1)^{th} semiconductor chip in an order of the first semiconductor chip to the (n−1)^{th} semiconductor chip, and forming an n^{th} insulating layer in contact with an upper surface of the n^{th} semiconductor chip. The chip connection process includes forming an mth insulating layer including a plurality of through-holes on an upper surface of an m^{th} semiconductor chip, forming a connection via and an upper pad of the m^{th} semiconductor chip in each of the plurality of through-holes, arranging solder nanoparticles inside the connection via, arranging an (m+1)^{th} semiconductor chip such that an upper surface of the connection via is coupled with a lower pad of the (m+1)^{th} semiconductor chip, and based on melting of the solder nanoparticles, forming a solder material layer filling a space at least partially surrounded by the upper pad of the mth semiconductor chip, the lower pad of the (m+1)^{th} semiconductor chip, and the connection via. n is a positive integer greater than one (1). m is a positive integer greater than or equal to one (1) and less than or equal to n−1.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 is a cross-sectional view schematically illustrating a semiconductor package, according to an embodiment;

FIG. 2A and FIG. 2B are cross-sectional views illustrating a bonding structure, according to embodiments;

FIG. 3 is a cross-sectional view schematically illustrating a semiconductor package, according to an embodiment; and

FIG. 4A to FIG. 4I are cross-sectional views illustrating a method of manufacturing a semiconductor package, according to an embodiment.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third“ to be used to describe relative positions of elements. The terms ”first,“ ”second,“ third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

It is to be understood that the specific order or hierarchy of blocks in the processes/flowcharts disclosed are an illustration of exemplary approaches. Based upon design preferences, it is understood that the specific order or hierarchy of blocks in the processes/flowcharts may be rearranged. Further, some blocks may be combined or omitted. The accompanying claims present elements of the various blocks in a sample order, and are not meant to be limited to the specific order or hierarchy presented.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

As used herein, each of the terms “GaAs”, “SiC”, “SiN”, “SiO”, “SiON”, and the like may refer to a material made of elements included in each of the terms and is not a chemical formula representing a stoichiometric relationship.

Hereinafter, various embodiments of the present disclosure are described with reference to the accompanying drawings.

As used herein, a horizontal direction may include a first horizontal direction (e.g., the X direction) and a second horizontal direction (e.g., the Y direction) that may intersect each other. A direction intersecting the first horizontal direction (the X direction) and the second horizontal direction (the Y direction) may be referred to as a vertical direction (the Z direction). As used herein, a vertical level may be referred to as a height level along a vertical direction (the Z direction) of any configuration.

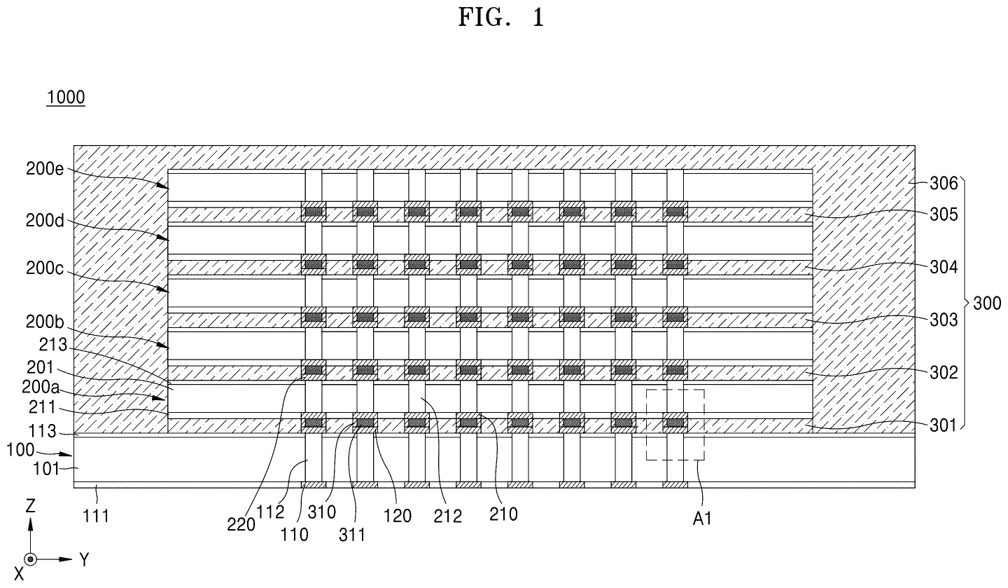

FIG. 1 is a cross-sectional view schematically illustrating a semiconductor package, according to an embodiment.

Referring to FIG. 1, a semiconductor package 1000 may include a plurality of semiconductor chips (e.g., a first semiconductor chip 100, a second semiconductor chip 200a, a third semiconductor chip 200b, a fourth semiconductor chip 200c, a fifth semiconductor chip 200d, and a sixth semiconductor chip 200e), an insulating structure 300, a plurality of connection vias 310, and a solder material layer 311.

The first semiconductor chip 100 may be arranged in a lowest layer. The first semiconductor chip 100 may be a semiconductor chip of a different type from the second to sixth semiconductor chips 200a to 200e that may be sequentially stacked on the first semiconductor chip 100. The first semiconductor chip 100 may have a relatively wide horizontal area compared to the second to sixth semiconductor chips 200a to 200e.

In some embodiments, the first semiconductor chip 100 may be and/or may include a buffer chip for controlling a high bandwidth memory (HBM) dynamic random access memory (DRAM) semiconductor chip. In such embodiments, the second to sixth semiconductor chips 200a to 200e may be HBM DRAM semiconductor chips.

In some embodiments, the first semiconductor chip 100 may be and/or may include, but not be limited to, a DRAM chip, a static random access memory (SRAM) chip, a flash memory chip, an electrically erasable and programmable read only memory (EEPROM) chip, a phase-change random access memory (PRAM) chip, a magnetic random access memory (MRAM) chip, a resistive random access memory (RRAM) chip, or the like. In some embodiments, the first semiconductor chip 100 may be and/or may include, for example, a central processing unit (CPU) chip, a graphics processing unit (GPU) chip, an application processor (AP) chip, or the like.

However, the above description is only one example, and the present disclosure is not limited in this regard. For example, the plurality of semiconductor chips 100 to 200e may be implemented as various types of semiconductor chips.

The first semiconductor chip 100 may be arranged in a face-down manner. That is, an active surface of the first semiconductor chip 100 may be arranged to face a vertical downward direction. In some embodiments, the first semiconductor chip 100 may be arranged in a face-up manner. That is, the arrangement of the first semiconductor chip 100 is not limited to the above description.

The first semiconductor chip 100 may include a first semiconductor substrate 101, first lower pads 110, a first lower passivation layer 111, a first through-electrodes 112, a first upper passivation layer 113, and first upper pads 120.

The first semiconductor substrate 101 may include a semiconductor material. For example, the first semiconductor substrate 101 may include a semiconductor element, such as silicon (Si) or germanium (Ge), or a compound semiconductor, such as, but not limited to, silicon carbide (SiC) or gallium arsenide (GaAs). The first semiconductor substrate 101 may include a conductive region, for example, a well doped with an impurity. The first semiconductor substrate 101 may also have various device isolation structures, such as, but not limited to, a shallow trench isolation (STI) structure.

The first lower pads 110 may be arranged on a lower side of the first semiconductor substrate 101. Side surfaces of the first lower pads 110 may be surrounded by the first lower passivation layer 111. That is, lower surfaces of the first lower pads 110 may be exposed to the outside without being surrounded by the first lower passivation layer 111. The first lower pads 110 may be respectively and electrically connected to the first through-electrodes 112. Although FIG. 1 illustrates that the first lower pads 110 are respectively and directly connected to the first through-electrodes 112, this is only for the sake of convenience of description, and the present disclosure is not limited in this regard. For example, the first lower pads 110 may also be respectively connected to the first through-electrodes 112 based on a plurality of wiring patterns inside the first semiconductor chip 100.

The first through-electrodes 112 may be respectively and electrically connected to the first lower pads 110 and the first upper pads 120. The first through-electrodes 112 may each pass through the first semiconductor substrate 101 and may each pass through a part of the first lower passivation layer 111 and a part of the first upper passivation layer 113. A through-insulating layer may be between the first through-electrode 112 and the first semiconductor substrate 101.

The first upper passivation layer 113 may be on an upper portion of the first semiconductor substrate 101, and the first upper pads 120 may be on the upper portion of the first upper passivation layer 113. For example, lower surfaces of the first upper pads 120 may be in contact with an upper surface of the first upper passivation layer 113.

The second to sixth semiconductor chips 200a to 200e may include the same configuration as the first semiconductor chip 100. Alternatively, the second to sixth semiconductor chips 200a to 200e may include different configurations from each other and/or from the first semiconductor chip 100. However, for the sake of convenience of description, only a configuration of the second semiconductor chip 200a may described in the present disclosure, and repeated descriptions of configurations of the third to sixth semiconductor chips 200b 200e may be omitted for the sake of brevity.

The second semiconductor chip 200a may include a second semiconductor substrate 201, second lower pads 210, a second lower passivation layer 211, second through-electrodes 212, a second upper passivation layer 213, and second upper pads 220.

The second lower pads 210 may be arranged on a lower side of the second semiconductor substrate 201, and side surfaces of the second lower pads 210 may be surrounded by the second lower passivation layer 211. The second through-electrodes 212 may be respectively and electrically connected to the second lower pads 210 and the second upper pads 220. The second upper pads 220 may be arranged on an upper portion of the second semiconductor substrate 201, and lower surfaces of the second upper pads 220 may each be in contact with an upper surface of the second upper passivation layer 213.

Each of the second semiconductor substrate 201, the second lower pads 210, the second lower passivation layer 211, the second through-electrodes 212, the second upper passivation layer 213, and the second upper pads 220 may have functions and/or structures that may include and/or may be similar in many respects to each of the first semiconductor substrate 101, the first lower pads 110, the first lower passivation layer 111, the first through-electrodes 112, the first upper passivation layer 113, and the first upper pads 120, respectively, and may include additional features not mentioned above. Consequently, repeated descriptions thereof may be omitted for the sake of brevity.

Connection vias 310 may each be disposed between two semiconductor chips that are arranged adjacent to each other among a plurality of semiconductor chips stacked in a vertical direction. For example, the connection vias 310 may be arranged between the first semiconductor chip 100 and the second semiconductor chip 200a. As another example, the connection vias 310 may also be arranged between the second semiconductor chip 200a and the third semiconductor chip 200b. The connection vias 310 may be a conductive layer having a preset thickness in a horizontal direction and extending in a vertical direction with a preset height. The connection vias 310 may each be composed of a low-resistance conductive material, such as, but not limited to, copper (Cu), aluminum (Al), silver (Ag), tin (Sn), gold (Au), nickel (Ni), lead (Pb), titanium (Ti), or an alloy thereof.

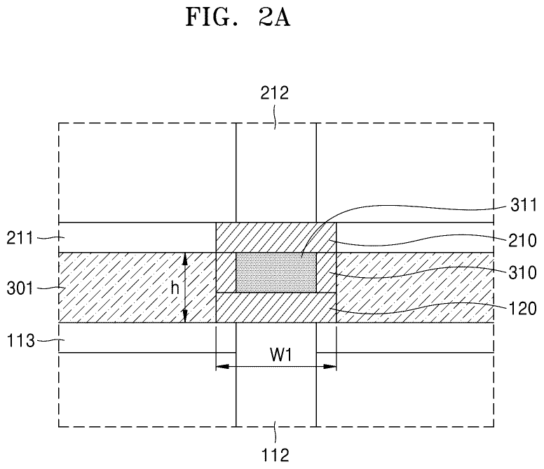

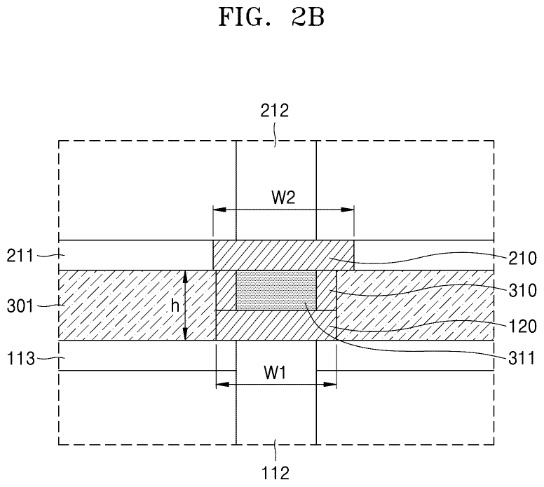

For example, the connection vias 310 may each be a conductive layer extending vertically from an upper pad of a lower-layer semiconductor chip to a lower pad of an upper-layer semiconductor chip. As used herein, the lower-layer semiconductor chip may refer to a semiconductor chip in a lower portion among two semiconductor chips that are adjacent to each other from among a plurality of semiconductor chips stacked vertically. In addition, the upper-layer semiconductor chip may refer to a semiconductor chip in an upper portion among the two semiconductor chips. Although, for the sake of convenience of description, FIGS. 1, 2A, and 2B are described below with the first semiconductor chip 100 being a lower-layer semiconductor chip and the second semiconductor chip 200a being an upper-layer semiconductor chip, the present disclosure is not limited in this regard. For example, the first semiconductor chip 100 may be an upper-layer semiconductor chip and the second semiconductor chip 200a may be lower-layer semiconductor chip.

A lower surface of the connection via 310 may be connected to an upper surface of the first upper pad 120, and an upper surface of the connection via 310 may be connected to a lower surface of the second lower pad 210.

According to one embodiment, the connection via 310 may have a cylindrical structure having opened upper portions and opened lower portions. The upper surface of the connection via 310 may be covered by the second lower pad 210, and the lower surface of the connection via 310 may be covered by the first upper pad 120. In such embodiments, a cylindrical region surrounded by the connection via 310, the first upper pad 120, and the second lower pads 210 may be formed.

According to an embodiment, the connection via 310 may have a truncated cone-shaped structure having opened upper portions and opened lower portions. The connection via 310 may have a truncated cone structure in which a horizontal cross-sectional area of an upper portion is greater than a horizontal cross-sectional area of a lower portion. In such an embodiment, the upper portion of the connection via 310 may be covered by the second lower pad 210, and the lower portion of the connection via 310 may be covered by the first upper pad 120. Therefore, the truncated cone-shaped region surrounded by the connection via 310, the first upper pad 120, and the second lower pad 210 may be formed.

The above description is only an example of a shape of the connection via 310, and the present disclosure is not limited in this regard. For example, the connection via 310 may have a structure of various shapes without departing from the scope of the present disclosure.

A solder material layer 311 may electrically and physically connect an upper-layer semiconductor chip to a lower-layer semiconductor chip. The solder material layer 311 may connect the first upper pad 120 to the second lower pad 210. The solder material layer 311 may be arranged inside the connection via 310.

According to an embodiment, an upper surface of the solder material layer 311 may be in contact with a lower surface of the second lower pad 210, a lower surface of the solder material layer 311 may be in contact with an upper surface of the first upper pad 120, and an outer surface of the solder material layer 311 may be in contact with an inner surface of the connection via 310. In addition, a void may not exist in the solder material layer 311. That is, the solder material layer 311 may fill a region surrounded by the connection via 310, the first upper pad 120, and the second lower pad 210.

For example, when the cylindrical region surrounded by the connection via 310, the first upper pad 120, and the second lower pad 210 is formed, the solder material layer 311 may have a substantially similar and/or the same shape as the cylindrical region. As another example, when a truncated cone-shaped region surrounded by the connection via 310, the first upper pad 120, and the second lower pad 210 is formed, the solder material layer 311 may have a substantially similar and/or the same shape as the truncated cone-shaped region.

According to an embodiment, the solder material layer 311 may include a material with an improved wettability when compared to materials of the connection via 310, the first upper pad 120, and the second lower pad 210. For example, the solder material layer 311 may include, but not be limited to, tin (Sn) or an alloy (Sn—Ag—Cu) including the tin (Sn).

In one embodiment, the solder material layer 311 may not be connected to the insulating structure 300. That is, the solder material layer 311 may not be in contact with (e.g., may be apart from) the insulating structure 300 because the solder material layer 311 is surrounded by the connection via 310, the first upper pad 120, and the second lower pad 210.

The connection via 310 and the solder material layer 311 described above may form a bonding structure that performs a function of bonding two adjacent semiconductor chips.

The insulating structure 300 may surround the plurality of first to sixth semiconductor chips 100 to 200e and a plurality of bonding structures. The insulating structure 300 may include a plurality of horizontal insulating layers (e.g., a first horizontal insulating layer 301, a second horizontal insulating layer 302, a third horizontal insulating layer 303, a fourth horizontal insulating layer 304, and a fifth horizontal insulating layer 305) and a molding layer 306. The plurality of first to fifth horizontal insulating layers 301 to 305 may have the same configuration and structure as each other, and accordingly, in the following description, only the first horizontal insulating layer 301 may described and repeated descriptions thereof may be omitted for the sake of brevity.

The first horizontal insulating layer 301 may be disposed between the first semiconductor chip 100 and the second semiconductor chip 200a and may surround outer surfaces of a plurality of connection vias 310 arranged between the first semiconductor chip 100 and the second semiconductor chip 200a. The first horizontal insulating layer 301 may surround an outer surface of the first upper pad 120. The solder material layer 311 may be in contact with an inner surface of the connection via 310, and the solder material layer 311 may not be connected to the first horizontal insulating layer 301.

The first horizontal insulating layer 301 may increase a bonding strength between the first semiconductor chip 100 and the second semiconductor chip 200a and may remove a space, into which foreign materials and/or moisture may penetrate, between the first semiconductor chip 100 and the second semiconductor chip 200a.

The molding layer 306 may surround side surfaces of the plurality of first to fifth horizontal insulating layers 301 to 305 and may surround an upper surface of an uppermost semiconductor chip (e.g., the sixth semiconductor chip 200e). The molding layer 306 may include the same material as the plurality of first to fifth horizontal insulating layers 301 to 305.

According to one embodiment, the plurality of first to fifth horizontal insulating layers 301 to 305 may include a photo imageable dielectric material, and the molding layer 306 may also include a photo imageable dielectric material. For example, the plurality of first to fifth horizontal insulating layers 301 to 305 and the molding layer 306 may each include, but not be limited to, at least one of polyhydroxyamide (PHA), polybenzoxazole (PBO), polyamic acid (PAA), and poly imide (PI).

As described above, the semiconductor package 1000, according to an embodiment, may include a molding layer formed of the same material as a horizontal insulating layer surrounding a bonding structure. Accordingly, the semiconductor package 1000 may potentially prevent an adhesive layer from performing an adhesive function between an upper-layer semiconductor chip and a lower-layer semiconductor chip from protruding from the outside of the molding layer 306 by thermal compression. That is, a horizontal insulating layer may be potentially prevented from protruding from the outside of the molding layer 306 because the semiconductor package 1000, according to an embodiment, includes the horizontal insulating layer that may perform the adhesive function and has the same material as the molding layer 306.

Although FIG. 1 illustrates only six (6) stacked semiconductor chips, the present disclosure is not limited in this regard. For example, the semiconductor package 1000, according to an embodiment, may include n semiconductor chips which are vertically stacked, where n is a positive integer greater than one (1).

Although FIG. 1 illustrates the second to sixth semiconductor chips 200a to 200e as being semiconductor chips of a same type, the present disclosure is not limited in this regard. For example, a plurality of semiconductor chips vertically stacked on the first semiconductor chip 100 may be and/or may include semiconductor chips of different types.

Although FIG. 1 illustrates only five (5) horizontal insulating layers, the present disclosure is not limited in this regard. That is, the semiconductor package 1000 may include a variety of horizontal insulating layers depending on the number of semiconductor chips stacked in a vertical direction. For example, when the semiconductor package 1000 includes n semiconductor chips, the semiconductor package 1000 may include (n−1) horizontal insulating layers.

FIG. 2A and FIG. 2B are cross-sectional views illustrating a bonding structure, according to an embodiment.

FIGS. 2A and 2B are enlarged cross-sectional views of a portion A1 of the semiconductor package 1000 of FIG. 1. Referring to FIG. 2A, the first horizontal insulating layer 301 may surround an outer surface of the connection via 310 and an outer surface of the first upper pad 120. The second lower pad 210 may be inside the second lower passivation layer 211.

According to an embodiment, a height h of the first horizontal insulating layer 301 may be equal to the sum of a height of the connection via 310 and a height of the first upper pad 120. The height h of the first horizontal insulating layer 301 may be about 1 micrometer (μm) to about 3 μm.

Additionally, a boundary of a lower surface of the connection via 310 may be arranged along a boundary of an upper surface of the first upper pad 120. For example, in a process of manufacturing the semiconductor package 1000, the connection via 310 may be connected to the first upper pad 120, and accordingly, the boundary of a lower surface of the connection via 310 may coincide with the boundary of the upper surface of the first upper pad 120. That is, as illustrated in FIG. 2A, when the upper surface of the first upper pad 120 has a horizontal width of W1, a horizontal width of the lower surface of the connection via 310 may also be W1.

In an embodiment, the arrangement of the connection via 310 connected to a lower surface of the second lower pad 210 may be changed depending on whether a horizontal width of the upper surface of the connection via 310 is equal to a horizontal width of the lower surface of the second lower pad 210.

According to an embodiment, as illustrated in FIG. 2A, the horizontal width of the upper surface of the connection via 310 and the horizontal width of the lower surface of the second lower pads 210 may be equal to each other as W1. In such an embodiment, the boundary of the upper surface of the connection via 310 may be arranged along a boundary of the lower surface of the second lower pad 210. That is, a central axis of the second lower pad 210, a central axis of the connection via 310, and a central axis of the first upper pad 120 may be on the same straight line.

According to an embodiment, as illustrated in FIG. 2B, a horizontal width of an upper surface of the connection via 310 may be W1, and a horizontal width of a lower surface of the second lower pad 210 may be W2, which may be larger (wider) than W1. In such an embodiment, a boundary of the upper surface of the connection via 310 may be within a boundary of the lower surface of the second lower pad 210. That is, a central axis of the second lower pad 210 and a central axis of the connection via 310 may be on different straight lines.

As illustrated FIGS. 2A and 2B, the first upper pad 120, the second lower pad 210, and the connection via 310 may form a region surrounded by the first upper pad 120, the second lower pad 210, and the connection via 310. In addition, the solder material layer 311 may fill the region surrounded by the first upper pad 120, the second lower pad 210, and the connection via 310, and may not be arranged in regions other than the region surrounded thereby. Accordingly, the semiconductor package 1000, according to an embodiment, may have a high bonding precision even when each of the first semiconductor chip 100 and the second semiconductor chip 200a includes multiple metal pads and pitches between the multiple metal pads are reduced.

For example, when bonding is made by using a plurality of solder bumps in a state where the pitches between the multiple metal pads are reduced, a problem may occur in which some of the plurality of solder bumps may spread in a horizontal direction to come into contact with other metal pads. Alternatively, the semiconductor package 1000, according to an embodiment, may include the solder material layer 311 arranged only in the region surrounded by the first upper pad 120, the second lower pad 210, and the connection via 310, and accordingly, the problem that some metal pads come into contact with other metal pads may be prevented.

In an embodiment, the first horizontal insulating layer 301 may be in contact with the first upper passivation layer 113 and the second lower passivation layer 211. In such an embodiment, the first horizontal insulating layer 301 may include a photo imageable dielectric material, and the first upper passivation layer 113 and the second lower passivation layer 211 may each include a low-k material, such as, but not limited to, silicon oxide (SiO), silicon oxynitride (SiON), or silicon nitride (SiN). The first horizontal insulating layer 301 formed of a photo imageable dielectric material may strongly and stably bonded to the first upper passivation layer 113 and the second lower passivation layer 211, each being formed of a material, such as, but not limited to, silicon oxide (SiO), silicon oxynitride (SiON), or silicon nitride (SiN). That is, the first horizontal insulating layer 301 formed of a photo imageable dielectric material may cause the first semiconductor chip 100 to be stably bonded to the second semiconductor chip 200a.

Although FIGS. 2A and 2B illustrate only the bonding structures between the first semiconductor chip 100 and the second semiconductor chip 200a, this is merely for the sake of convenience of description, and the present disclosure is not limited in this regard. For example, the bonding structures between the other semiconductor chips may also include the configuration illustrated in FIGS. 2A and 2B.

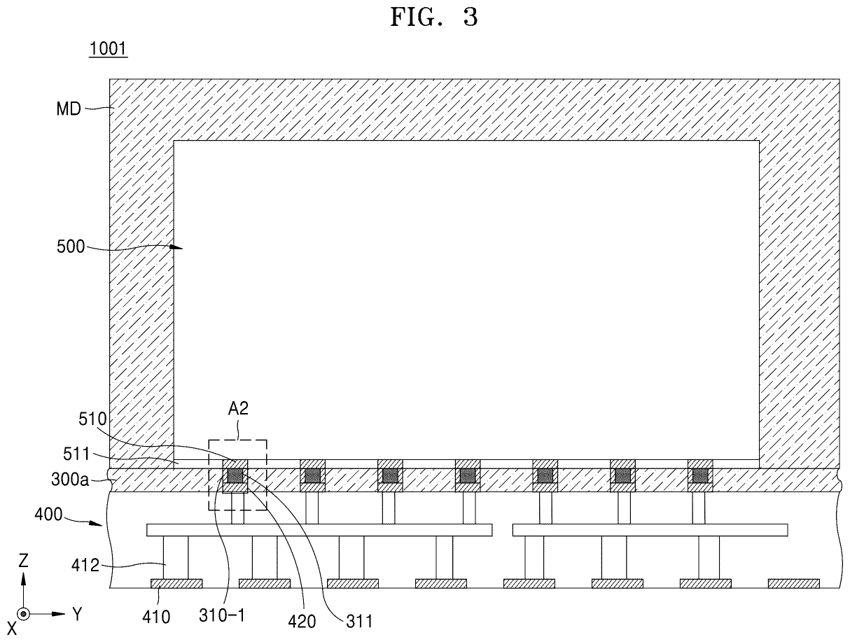

FIG. 3 is a cross-sectional view schematically illustrating a semiconductor package, according to an embodiment.

Referring to FIG. 3, a semiconductor package 1001 may include an insulating structure, bonding structures, a substrate 400, and a semiconductor device 500.

The substrate 400 may be implemented as at least one of a package substrate (e.g., a printed circuit board (PCB)), an interposer substrate, and a redistribution layer. That is, the substrate 400 may be and/or may include a configuration in which a semiconductor device is arranged on an upper portion and signal paths of the semiconductor device are provided. The substrate 400 may include lower pads 410, upper pads 420, and internal redistribution patterns 412, respectively and electrically, connecting the lower pads 410 to the upper pads 420. According to an embodiment, the substrate 400 may include, but not be limited to, a thermosetting resin such as an epoxy resin, a thermoplastic resin such as polyimide, a resin impregnated with a reinforcing material such as glass fiber, an inorganic filler (e.g., prepreg), and/or a photocurable resin.

The semiconductor device 500 may be on the substrate 400. The semiconductor device 500 may include at least one semiconductor chip and an insulating material. The semiconductor device 500 may include a lower passivation layer 511 and lower pads 510. For example, the semiconductor device 500 may include and/or may be similar in many respects to the semiconductor package 1000 described with reference to FIG. 1, and may include additional features not mentioned above. Consequently, repeated descriptions of the semiconductor device 500 described above with reference to FIG. 1 may be omitted for the sake of brevity.

The bonding structures may be disposed between the semiconductor device 500 and the substrate 400 and may respectively include connection vias 310-1 and solder materials layer 311. The insulating structure may surround the semiconductor device 500 and the connection vias 310-1 and may include a horizontal insulating layer 300a and a molding layer MD.

The connection vias 310-1 and the solder material layers 311 may respectively connect the upper pads 420 of the substrate 400 to the lower pads 510 of the semiconductor device 500. As used herein, a method of connecting the upper pads 420 to the lower pads 510 based on the connection vias 310-1 and the solder material layers 311 overlaps the method described above, and accordingly, redundant descriptions thereof are omitted. That is, a portion A2 of FIG. 3 may have a substantially similar and/or the same configuration and structure as a portion Al illustrated in FIG. 1 to FIG. 2B.

The horizontal insulating layer 300a may be on an upper surface of the substrate 400 and may surround outer surfaces of the connection vias 310-1 and outer surfaces of the upper pads 420. In an embodiment, the horizontal insulating layer 300a may include a photo imageable dielectric material, and a height of the horizontal insulating layer 300a may be about 1 μm to about 3 μm. The configuration and structure of the horizontal insulating layer 300a may be substantially similar and/or the same as the configuration and structure of the first horizontal insulating layer 301 described with reference to FIGS. 1 to 2B, and accordingly, repeated descriptions thereof may be omitted for the sake of brevity.

The molding layer MD may surround an upper surface of the horizontal insulating layer 300a and a side surface of the semiconductor device 500. The molding layer MD may include the same material as the horizontal insulating layer 300a. According to one embodiment, the molding layer MD and the horizontal insulating layer 300a may be formed of the same photo imageable dielectric material.

However, the above description is only one example, and the molding layer MD and the horizontal insulating layer 300a may include different materials. For example, the horizontal insulating layer 300a may include a photo imageable dielectric material, and the molding layer MD may include an epoxy molding compound (EMC).

In the semiconductor package 1001, according to an embodiment, a connection between the substrate 400 and the semiconductor device 500 may be made based on the connection vias 310-1, the solder material layers 311, and the horizontal insulating layer 300a. Accordingly, a connection distance between the substrate 400 and the semiconductor device 500 may be minimized, and an electric signal which may be generated between the substrate 400 and the semiconductor device 500 may be prevented from being leaked.

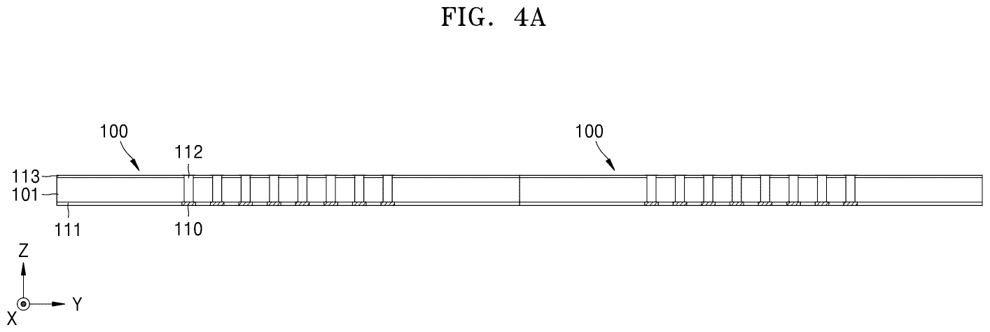

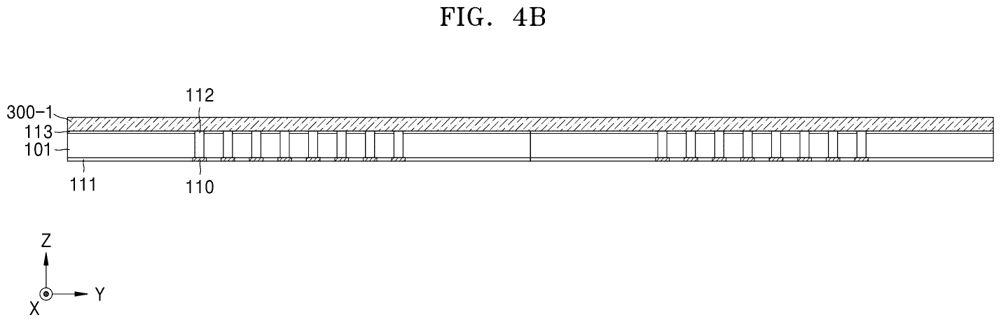

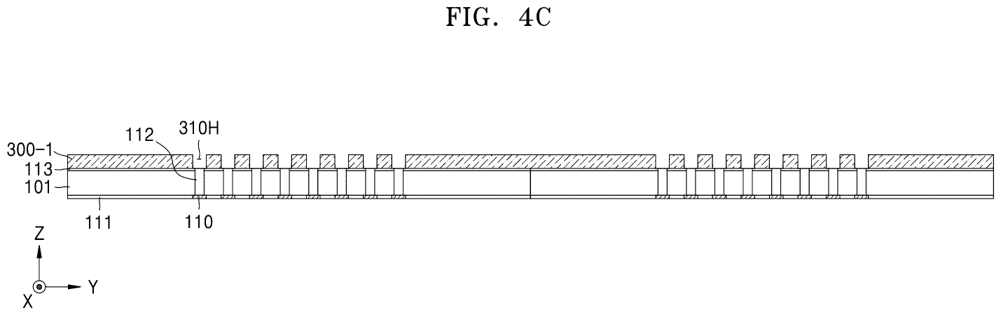

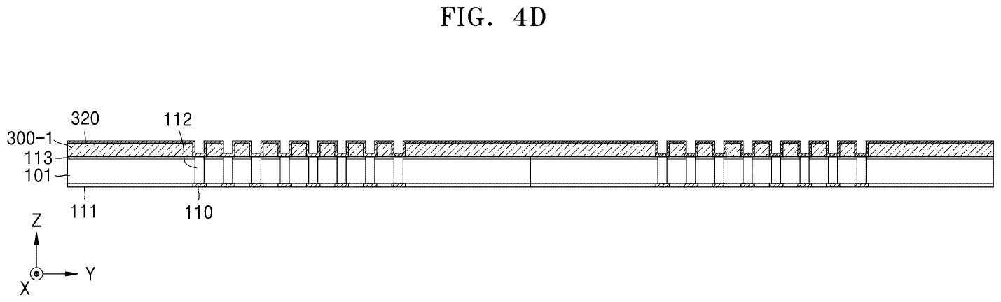

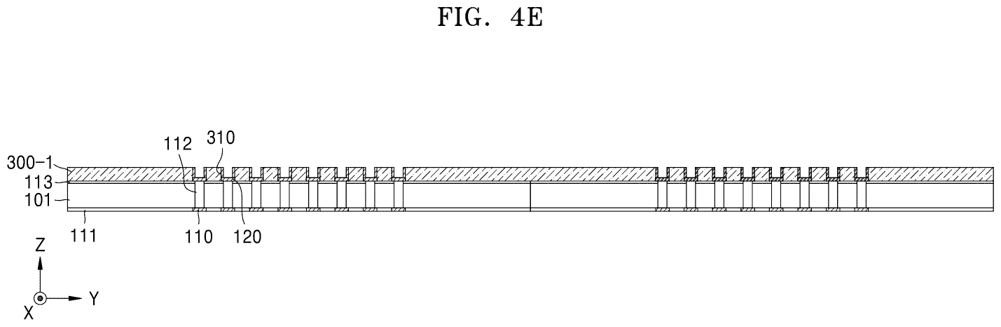

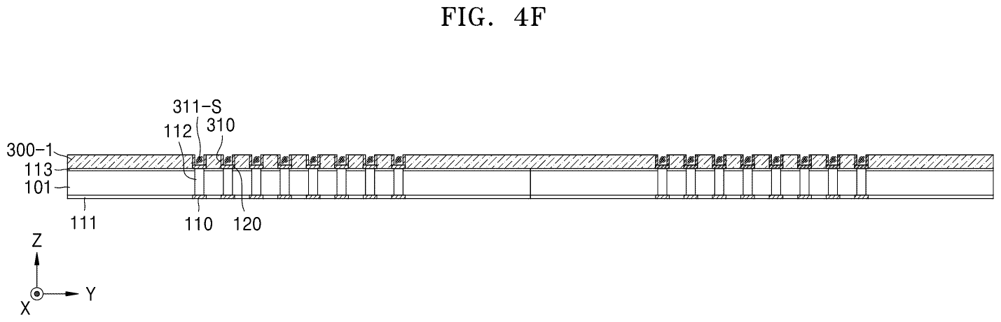

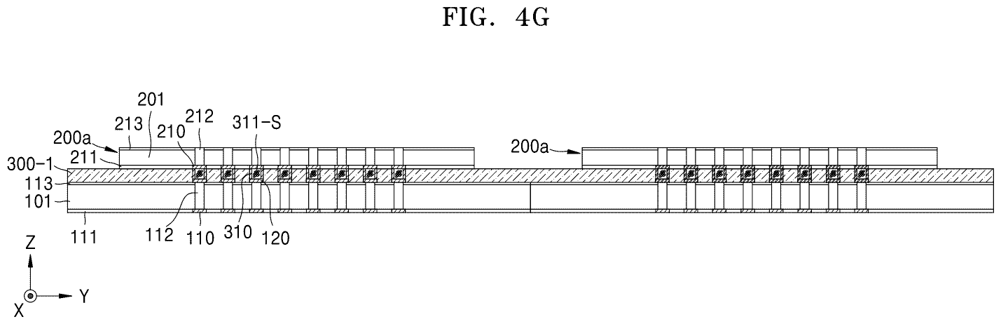

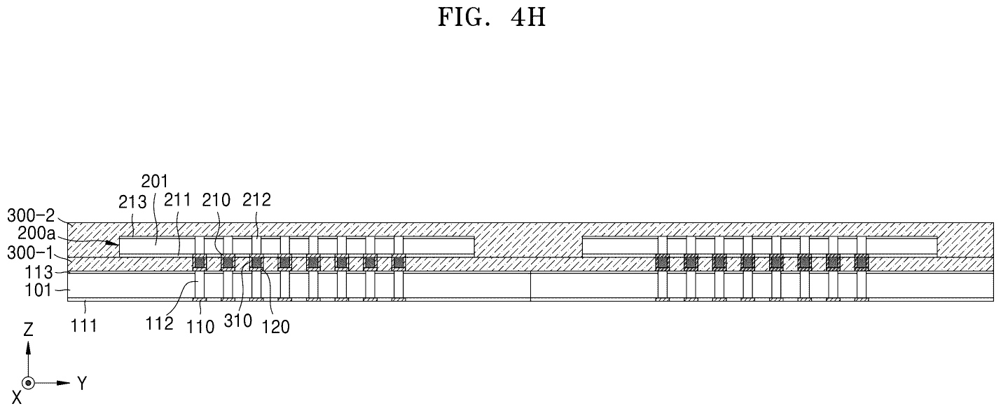

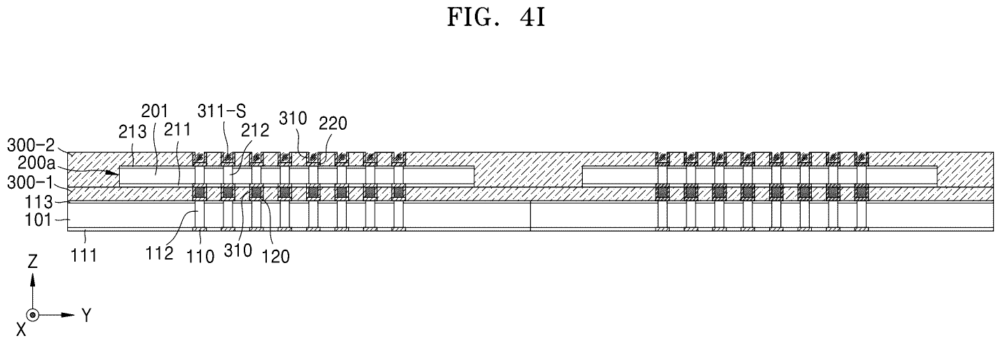

FIGS. 4A to 4I illustrate a method of manufacturing the semiconductor package described above.

FIG. 4A to FIG. 4I are cross-sectional views illustrating a method of manufacturing a semiconductor package, according to an embodiment.

Referring to FIG. 4A, a first semiconductor chip 100 is prepared. An operation of preparing a first semiconductor chip 100 may include an operation of preparing a wafer including a plurality of first semiconductor chips 100. The first semiconductor chip 100 may include first lower pads 110, a first lower passivation layer 111, first through-electrodes 112, and a first upper passivation layer 113.

The operation of preparing the first semiconductor chip 100 may include an operation of preparing a second semiconductor chip to an nth semiconductor chip. The second semiconductor chip to the nth semiconductor chip may have the same configuration as the first semiconductor chip 100. For example, a second semiconductor chip 200a may include second lower pads 210, a second lower passivation layer 211, second through-electrodes 212, and a second upper passivation layer 213.

Subsequently, a chip connection process may be sequentially performed to connect the first semiconductor chip to an (n−1)^{th} semiconductor chip in an order of the first semiconductor chip to the (n−1)th semiconductor chip. The chip connection processes performed for the first semiconductor chip to the (n−1)th semiconductor chip may all be performed in the same method and in the same order, and accordingly, for the sake of convenience of description, only the chip connection process of connecting the first semiconductor chip 100 to the second semiconductor chip 200a may be described as an example.

Referring to FIGS. 4B and 4C, a first insulating layer 300-1 including a plurality of through-holes 310H may be formed on an upper surface of the first semiconductor chip 100.

As shown in FIG. 4B, a photo imageable dielectric material may be applied onto an upper surface of the first semiconductor chip 100 by a preset height, and the applied photo imageable dielectric material may be cured. The preset height may be about 1 micrometer (μm) to about 3 μm. In addition, the coating of the photo imageable dielectric material may be performed based on various methods of coating the photo imageable dielectric material on an upper surface of the first semiconductor chip 100 by using a liquid-state photo imageable dielectric material, such as spin coating or slot die coating. The curing of the photo imageable dielectric material may be performed at about 150° C.

Referring to FIG. 4C, the plurality of through-holes 310H may be formed in the first insulating layer 300-1. Positions where the plurality of through-layer 300-1 are formed may be the positions that respectively overlap the first through-electrodes 112 in a vertical direction. That is, when the plurality of through-holes 310H are formed, upper surfaces of the first through-electrode 112 may be exposed to the outside. An exposure process and a development process may be performed to form the plurality of through-holes 310H.

According to an embodiment, an exposure process may be performed to prevent light from reaching a portion, in which the plurality of through-holes 310H are to be formed, in the entire region of the first insulating layer 300-1 and to allow the light to reach the other portions. Subsequently, the plurality of through-holes 310H may be formed by exposing the first insulating layer 300-1 to a developer to remove an insulating material in a region where the light does not reach.

The method described above is only an example method of forming the plurality of through-holes 310H in the first insulating layer 300-1, and the present disclosure is not limited in this regard. That is, the first insulating layer 300-1 including the plurality of through-holes 310H may be formed based on various methods. For example, the plurality of through-holes 310H may be formed through a laser drilling process.

Referring to FIGS. 4D and 4E, a plurality of connection vias 310 and a plurality of first upper pads 120 may be respectively formed in the plurality of through-holes 310H.

As shown in FIG. 4D, a metal material layer 320 may be deposited on lower surfaces and side surfaces of the plurality of through-holes 310H and an upper surface of the first insulating layer 300-1. The metal material layer 320 may be formed of a low-resistance conductive material, such as, but not limited to, copper (Cu), aluminum (Al), silver (Ag), tin (Sn), gold (Au), nickel (Ni), lead (Pb), titanium (Ti), or an alloy thereof. A deposition process of the metal material layer 320 may be performed based on at least one process selected from various deposition processes, such as, but not limited to, a physical vapor deposition (PVD) process, a chemical vapor deposition (CVD) process, and an atomic layer deposition (ALD) process.

As shown in FIG. 4E, only the metal material layer, which is on an upper surface of the first insulating layer 300-1, in the entire metal material layer 320 illustrated in FIG. 4D may be removed. When the metal material layer on the upper surface of the first insulating layer 300-1 is removed, only the metal material layer on the lower surfaces and side surfaces of the plurality of through-holes 310H may remain. Portions of the metal material layer on the lower surfaces of the plurality of through-holes 310H may be the plurality of first upper pads 120, and portions of the metal material layer which are arranged on the side surfaces of the plurality of through-holes 310H may be the plurality of connection vias 310.

According to an embodiment, the removal of the metal material layer described above may be performed based on a polishing process. That is, the polishing process may be performed on the metal material layer 320 until an upper surface of the first insulating layer 300-1 is exposed to the outside. The removal process of the metal material layer 320 may be performed through a chemical mechanical polishing (CMP) process but is not limited to the above-described example.

Referring to FIG. 4F, solder nanoparticles 311-S may be arranged in each of the plurality of connection vias 310. The solder nanoparticles 311-S may refer to solid-state solder materials having a small size. For example, the solder nanoparticles 311-S may be and/or may include solid-state solder materials, each having a spherical shape with a radius of 50 nm. The solder nanoparticles 311-S may each include tin (Sn) or an alloy (Sn—Ag—Cu) including tin (Sn).

The nanoparticle 311-S, each having a preset mass, may be in any one of the plurality of connection vias 310. The preset mass may be determined based on a height of any one of the plurality of connection vias 310 and a width of any of the plurality of first upper pads 120. According to an embodiment, the preset mass may be proportional to the height of any one of the plurality of connection vias 310 and the width of any one of the plurality of first upper pads 120. For example, when the height of any one of the plurality of connection vias 310 is 3 μm and the width of any one of the plurality of first upper pads 120 is 10 μm, the preset mass may be 3 milligram (mg), and when the height of any one of the plurality of connection vias 310 is 1 μm and the width of any one of the plurality of first upper pads 120 is 10 μm, the preset mass may be 1 mg.

As described above, the mass of each of the solder nanoparticles 311-S may be changed depending on the height of each of the plurality of connection vias 310 and the width of each of the plurality of first upper pads 120. Accordingly, a relatively large amount of solder nanoparticles 311-S may be injected into an internal space of each of the plurality of connection vias 310, and accordingly, it may be possible to prevent solder materials from being exposed to the outside of the plurality of connection vias 310.

The process of arranging the solder nanoparticles 311-S as described above may be performed by using a mask. By using the mask, the solder nanoparticles 311-S may be arranged only inside the plurality of connection vias 310.

Referring to FIG. 4G, the second semiconductor chip 200a may be arranged on the first insulating layer 300-1 such that upper surfaces of the plurality of connection vias 310 are respectively connected to the second lower pads 210 of the second semiconductor chip 200a.

An operation of arranging the second semiconductor chip 200a on the first insulating layer 300-1 may include an operation of aligning the second semiconductor chip 200a with the first semiconductor chip 100 such that boundaries of the upper surfaces of the connection vias 310 are respectively arranged within boundaries of lower surfaces of the second lower pads 210 of the second semiconductor chip 200a.

As described above with reference to FIG. 1 to FIG. 2B, the second semiconductor chip 200a may be aligned with the first semiconductor chip 100 such that the boundaries of the upper surfaces of the connection vias 310 may be respectively arranged within the boundaries of the lower surfaces of the second lower pads 210, and accordingly, the solder nanoparticles 311-S may be arranged in a space surrounded by the first upper pad 120, the second lower pad 210, and the connection via 310. Therefore, electric signals may be transmitted between the first semiconductor chip 100 and the second semiconductor chip 200a without leakage.

Referring to FIG. 4H, a solder material layer 311 for filling a space surrounded by the first upper pad 120, the second lower pad 210, and the connection via 310 may be formed based on the melting of the solder nanoparticles 311-S.

A thermal compression process may be performed to melt the solder nanoparticles 311-S. In the thermal compression process, the solder nanoparticles 311-S may be heated to a temperature higher than a melting point. For example, when the solder nanoparticles 311-S are tin-lead (Sn-Pb) alloys, the thermal compression process may be a process of exposing the solder nanoparticles 311-S to an environment of 183° C. or higher. In addition, the thermal compression process may include a process of applying a pressure of about 10 Newtons per square centimeter (N/cm²) to about 100 N/cm², in a vertical downward direction, to the first semiconductor chip 100 and the second semiconductor chip 200a from above the second semiconductor chip 200a.

Based on the same method as described with reference to FIG. 4B to form the first insulating layer 300-1, a second insulating layer 300-2 may be formed on an upper surface of the second semiconductor chip 200a.

Specifically, the second insulating layer 300-2 may surround the upper surface and a side surface of the second semiconductor chip 200a and may be arranged on an upper surface of the first insulating layer 300-1. The second insulating layer 300-2 may be formed to have a preset height from an upper surface of the second semiconductor chip 200a, and the preset height may be about 1 μm to about 3 μm.

Referring to FIG. 4I, a plurality of through-holes may be formed in the second insulating layer 300-2 and solder nanoparticles 311-S may be arranged in the plurality of through-holes. A method of forming the plurality of through-holes in the second insulating layer 300-2 and arranging the solder nanoparticles 311-S may be substantially similar and/or the same as the method of forming a plurality of through-holes in the first insulating layer 300-1 and arranging the solder nanoparticles 311-S therein, and accordingly, repeated descriptions thereof may be omitted for the sake of brevity.

Although FIGS. 4B to 4I only illustrate the chip connection process between the first semiconductor chip 100 and the second semiconductor chip 200a, this is merely for the sake of convenience of description, and the present disclosure is not limited in this regard. For example, a chip connection process between the second semiconductor chip 200a and the third semiconductor chip 200b and a chip connection process between the third semiconductor chip 200b and the fourth semiconductor chip 200c may also be performed based on a substantially similar and/or the same method as the method described above. The chip connection process may be performed in order of the first semiconductor chip 100, the second semiconductor chip 200a, the third semiconductor chip 200b, to the nth semiconductor chip 200n.

For example, the third semiconductor chip 200b may be arranged on the second insulating layer 300-2 as illustrated in FIG. 4I, and the solder material layer 311 may be formed between the second semiconductor chip 200a and the third semiconductor chip 200b based on the melting of the solder nanoparticles 311-S.

However, the chip connection process may not be performed for an uppermost semiconductor chip arranged on an uppermost layer of a semiconductor package. For example, it may be assumed that the uppermost semiconductor chip is an n^{th} semiconductor chip, and a semiconductor chip on a lower layer of the n^{th} semiconductor chip is an (n−1)^{th} semiconductor chip. In this case, a solder material layer is provided between the (n−1)^{th} semiconductor chip and the n^{th} semiconductor chip, and the solder material layer is not provided on an n^{th} insulating layer arranged on an upper surface of the n^{th} semiconductor chip. Therefore, the nth insulating layer may be connected to an (n−1)^{th} insulating layer formed on a lower layer of the n^{th} semiconductor chip and may perform a function of protecting the n^{th} semiconductor chip and insulating the n^{th} semiconductor chip from the outside.

Subsequently, according to an embodiment, an individualization process of individualizing a plurality of semiconductor chips illustrated in FIG. 4I may be performed. Through the individualization process, the first semiconductor chip to the n^{th} semiconductor chip are vertically stacked, and accordingly, a semiconductor package may be manufactured.

The semiconductor package 1000, according to an embodiment, may be manufactured through the process described above in detail with reference to FIGS. 4A to 4I.

Although the present disclosure is described with reference to the embodiments illustrated in the drawings, this is merely an example, and those of skill in the art may understand that various modifications and equivalent other embodiments may be derived therefrom. Therefore, the scope of the present disclosure may be determined by the technical idea of the appended patent claims.

While the present disclosure has been particularly shown and described with reference to embodiments thereof, it is to be understood that various changes in form and details may be made therein without departing from the spirit and scope of the following claims.

What is claimed is:

1. A semiconductor package, comprising:
a plurality of semiconductor chips stacked in a vertical direction, the plurality of semiconductor chips comprising a first semiconductor to an n^{th} semiconductor chip, n being a positive integer greater than one (1);
a plurality of bonding structures coupling two adjacent semiconductor chips from among the plurality of semiconductor chips, the two adjacent semiconductor chips comprising a lower-layer semiconductor chip and an upper-layer semiconductor chip; and
an insulating structure at least partially surrounding the plurality of semiconductor chips and the plurality of bonding structures;
wherein each bonding structure of the plurality of bonding structures comprises a connection via and a solder material layer,
wherein the connection via extends vertically from an upper pad of the lower-layer semiconductor chip to a lower pad of the upper-layer semiconductor chip, and
wherein the solder material layer is inside the connection via.

2. The semiconductor package of claim 1, wherein an upper surface of the solder material layer is in contact with a lower surface of the lower pad of the upper-layer semiconductor chip,
wherein a lower surface of the solder material layer is in contact with an upper surface of the upper pad of the lower-layer semiconductor chip, and
wherein an outer surface of the solder material layer is in contact with an inner surface of the connection via.

3. The semiconductor package of claim 2, wherein an outer surface of the connection via is at least partially surrounded by the insulating structure,
wherein an outer surface of the upper pad of the lower-layer semiconductor chip is at least partially surrounded by the insulating structure, and
wherein the solder material layer is apart from the insulating structure.

4. The semiconductor package of claim 1, wherein the connection via has a cylindrical structure with open upper portions and open lower portions, and
wherein a boundary of a lower surface of the connection via is disposed along a boundary of an upper surface of the upper pad of the lower-layer semiconductor chip.

5. The semiconductor package of claim 4, wherein a boundary of an upper surface of the connection via is disposed within a boundary of a lower surface of the lower pad of the upper-layer semiconductor chip.

6. The semiconductor package of claim 1, wherein the insulating structure comprises a photo imageable dielectric material, and
wherein the connection via, the upper pad of the lower-layer semiconductor chip, and the lower pad of the upper-layer semiconductor chip comprise a same metal material.

7. The semiconductor package of claim 1, wherein the insulating structure comprises:
a plurality of horizontal insulating layers respectively provided between the plurality of semiconductor chips, the plurality of horizontal insulating layers comprising a first horizontal insulating layer to an (n−1)^{th} horizontal insulating layer; and
a molding layer comprising a same material as the plurality of horizontal insulating layers,
wherein at least one horizontal insulating layer of the plurality of horizontal insulating layers is disposed between the two adjacent semiconductor chips, at least partially surrounds an outer surface of the connection via, and at least partially surrounds an outer surface of the upper pad of the lower-layer semiconductor chip, and
wherein the molding layer at least partially surrounds an upper surface of an uppermost semiconductor chip from among the plurality of semiconductor chips, side surfaces of the second semiconductor chip to the nth semiconductor chip, and side surfaces of the plurality of horizontal insulating layers.

8. The semiconductor package of claim 7, wherein a height of the plurality of horizontal insulating layers is equal to a sum of a height of the connection via and a height of the upper pad of the lower-layer semiconductor chip.

9. The semiconductor package of claim 7, wherein the height of the plurality of horizontal insulating layers ranges from 1 micrometer (μm) to 3 μm.

10. A semiconductor package, comprising:
a substrate;
a semiconductor device on an upper portion of the substrate and comprising at least one semiconductor chip;
a plurality of bonding structures coupling the substrate with the semiconductor device; and
an insulating structure on an upper surface of the substrate and at least partially surrounding the plurality of bonding structures,
wherein each of the plurality of bonding structures comprises a connection via and a solder material layer,
wherein the connection via extends vertically from a lower pad of the semiconductor device to an upper pad of the substrate,
wherein an upper surface of the solder material layer is in contact with a lower surface of the lower pad of the semiconductor device,
wherein a lower surface of the solder material layer is in contact with an upper surface of an upper pad of the substrate, and
wherein an outer surface of the solder material layer is in contact with an inner surface of the connection via.

11. The semiconductor package of claim 10, wherein an outer surface of the connection via at least partially surrounded by the insulating structure,
wherein an outer surface of the upper pad of the substrate at least partially surrounded by the insulating structure, and
wherein the solder material layer is apart from the insulating structure.

12. The semiconductor package of claim 10, wherein the connection via is a cylindrical structure with open upper portions and open lower portions,
wherein a boundary of a lower surface of the connection via is disposed along a boundary of the upper surface of the upper pad of the substrate, and
wherein a boundary of an upper surface of the connection via is disposed within a boundary of the lower surface of the lower pad of the semiconductor device.

13. The semiconductor package of claim 10, wherein the insulating structure comprises a photo imageable dielectric material, and
wherein the connection via, the lower pad of the semiconductor device, and the upper pad of the substrate comprise a same metal material.

14. The semiconductor package of claim 10, wherein the insulating structure comprises a molding layer at least partially surrounding an upper surface of a horizontal insulating layer provided between the substrate and the semiconductor device and a side surface of the semiconductor device, and
wherein the horizontal insulating layer at least partially surrounds an outer surface of the connection via and at least partially surrounds an outer surface of the upper pad of the substrate.

15. The semiconductor package of claim 14, wherein a height of the horizontal insulating layer ranges from 1 micrometer (μm) to 3 μm.

16. A semiconductor package, comprising:
a plurality of semiconductor chips stacked in a vertical direction; and
a plurality of bonding structures coupling two adjacent semiconductor chips from among the plurality of semiconductor chips, the two adjacent semiconductor chips comprising a lower-layer semiconductor chip and an upper-layer semiconductor chip;
wherein each bonding structure of the plurality of bonding structures comprises a connection via and a solder material layer,
wherein the solder material layer extends vertically from a lower surface of the upper-layer semiconductor chip to an upper pad of the lower-layer semiconductor chip, and
wherein the connection via at least partially surrounds the solder material layer.

17. The semiconductor package of claim 16, wherein an upper surface of the solder material layer is in contact with the lower surface of the upper-layer semiconductor chip, and
wherein a lower surface of the solder material layer is in contact with an upper surface of the upper pad of the lower-layer semiconductor chip.

18. The semiconductor package of claim 16, wherein the connection via has a cylindrical structure, and
wherein a boundary of a lower surface of the connection via is disposed along a boundary of an upper surface of the upper pad of the lower-layer semiconductor chip.

19. The semiconductor package of claim 18, wherein a boundary of an upper surface of the connection via is disposed within a boundary of a lower surface of a lower pad of the upper-layer semiconductor chip.

20. The semiconductor package of claim 16, further comprising:
an insulating structure at least partially surrounding the plurality of semiconductor chips and the plurality of bonding structures;
wherein the insulating structure comprises a photo imageable dielectric material,
wherein the connection via, the upper pad of the lower-layer semiconductor chip, and a lower pad of the upper-layer semiconductor chip comprise a same metal material.
